(19) United States
(12) Patent Application Publication
(10) Pub. No.: US 2008/0236753 A1
(43) Pub. Date: Oct. 2, 2008

(54) PLASMA PROCESSING APPARATUS

(75) Inventor: Yohei YAMAZAWA, Nirasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Minato-ku (JP)

(21) Appl. No.: 12/056,577

(22) Filed: Mar. 27, 2008

Related U.S. Application Data
(60) Provisional application No. 60/940,107, filed on May 25, 2007.

(30) Foreign Application Priority Data
Mar. 28, 2007 (JP) 2007-084110

(51) Int. Cl. C23F 1/08; C23C 16/503

(52) U.S. Cl. 156/345.43; 118/723 E

(57) ABSTRACT

A plasma processing apparatus includes a processing chamber; a high frequency electrode provided in the processing chamber; a high frequency power supply for applying a high frequency power to the high frequency electrode; a facing electrode attached to the processing chamber in an electrically floating state; and a facing ground potential portion provided around the facing electrode. The apparatus further includes an impedance controller for variably controlling an impedance of a high frequency power transmitting pass extending from the facing electrode to a ground potential; a processing gas supply unit for supplying a processing gas into a processing space between the high frequency electrode and the facing electrode, and the facing ground potential portion; and a dielectric plate arranged within the processing chamber for covering a surface of the facing ground potential portion.

### FIELD OF THE INVENTION

The present invention relates to a technique of performing plasma processing on a target substrate to be processed and, more specifically, to a capacitively coupled plasma processing apparatus that generates a plasma by applying a high frequency power to an electrode.

### BACKGROUND OF THE INVENTION

In a manufacturing process of a semiconductor device or an FPD (Flat Panel Display), a plasma is used for a treatment such as etching, deposition, oxidation, sputtering or the like so that a reaction of a processing gas can be carried out at a relatively low temperature. Conventionally, a capacitively coupled plasma processing apparatus capable of easily generating a large-diameter plasma is mainly used as a single wafer plasma processing apparatus, more particularly as a plasma etching apparatus.

In general, the capacitively coupled plasma processing apparatus includes a vacuum processing chamber. An upper and a lower electrode are arranged within the processing chamber in a parallel relationship. A target substrate to be processed (such as a semiconductor wafer, a glass substrate or the like) is mounted on the lower electrode. A high frequency voltage is applied to one of the upper and the lower electrode. Electrons are accelerated by a high frequency electric field generated by the high frequency voltage, and ionization by collision between the electrons and the processing gas generates a plasma. Desired fine processing, e.g., etching, is performed on the surface of the target substrate by radicals and/or ions in the plasma. Here, the electrode to which the high frequency voltage is applied serves as a cathode because it is connected to a high frequency power supply via a blocking capacitor in a matching unit. In a cathode-coupled plasma processing apparatus applying a high frequency power to a lower electrode to serve as a cathode, ions in the plasma is injected to a substrate in an almost perpendicular direction by a self-bias voltage generated at the lower electrode, thereby making it possible to perform anisotropic etching (see, e.g., Japanese Patent Laid-open Application No. 2004-096066).

In order to increase the production yield in single wafer plasma processing, there is a need to reduce variations of process characteristics between the central portion and the peripheral (edge) portion of a substrate to a greatest possible extent. In case of a capacitively coupled plasma processing apparatus, the plasma density distribution may become non-uniform in a radial direction as the substrate and the plasma become greater in diameter. In general, the plasma density is likely to grow relatively high in the central portion of the substrate but relatively low in the peripheral portion of the substrate. The non-uniformity in the plasma density causes variations of process characteristics, and further deteriorates the production yield. For this reason, there is a need for a technique for making the plasma density distribution uniform or a technique of controlling the plasma density distribution in an arbitrary profile.

There is known a method in which an anode side electrode, i.e., a facing electrode, is not directly grounded but grounded via variable impedance (electrode impedance) in order to control the plasma density distribution. In this method, the electrode impedance is varied to change the current density just below or above the electrode, thereby controlling the current density distribution, and further controlling the plasma density distribution in a radial direction of the electrode. In practice, however, a surrounding ground potential portion serves as a low impedance pass through which a considerable amount of electric current flows. Therefore, even if the impedance is changed sufficiently large, a small change occurs in the plasma density distribution. In other words, the effect of controlling the plasma density distribution remains small, which leads to a failure to obtain a sufficient effect. In particular, this problem becomes more noticeable as the RF power is increased.

### SUMMARY OF THE INVENTION

In view of the above-noted problems, the present invention provides a plasma processing apparatus capable of improving the effect of an electrode impedance control function and effectively controlling a plasma density distribution.

In accordance with an aspect of the present invention there is provided a plasma processing apparatus including: a vacuum-evacuable processing chamber; a high frequency electrode provided in the processing chamber in an electrically floating state; a high frequency power supply for applying a high frequency power to the high frequency electrode; a facing electrode attached to the processing chamber in an electrically floating state to face the high frequency electrode; a facing ground potential portion provided around the facing electrode in a grounded state; an impedance controller for variably controlling an impedance of a high frequency power transmitting pass extending from a surface of the facing electrode to a ground potential; a processing gas supply unit for supplying a processing gas into a processing space between the high frequency electrode, and the facing electrode and the facing ground potential portion; and a dielectric plate arranged within the processing chamber to cover a surface of the facing ground potential portion.

With the apparatus configuration described above, the surface of the facing ground potential portion is covered by the dielectric plate. Therefore, it is possible to directly increase the impedance of the surface of the facing ground potential portion. It is also possible to relatively increase the influence (action) of the electrode that serves to vary the impedance. This allows the impedance controller to vary the electrode impedance and to locally and effectively control (raise or lower) the plasma density in the region just below or just above the facing electrode, while restraining the influence on the plasma density (the fluctuation of the plasma density) in the region just below or just above the facing ground potential portion. Further, it becomes possible to arbitrarily control the profile of the plasma density distribution in the processing space above the target substrate.

Preferably, the dielectric plate is directly attached to the surface of the facing ground potential portion. In this case the dielectric plate may be attached to the surface of the facing ground potential portion by a bolt made of resin.

The dielectric plate may have a thickness varying in a radial direction of the facing electrode. For example, the dielectric plate may have a thickness gradually reducing in a radial outward direction of the electrode. Such a change in the thickness of the dielectric plate makes it possible to two-dimensionally change the impedance of the surface of the facing ground potential portion.

Although the dielectric plate may be a ceramic plate, it is particularly preferred that the dielectric plate is a quartz plate that has a low dielectric constant and a superior resistance against plasma.

The high frequency electrode may mount a target substrate thereon. In this case, the facing electrode and the facing ground potential portion are preferably provided with gas injection openings through which the processing gas fed from the processing gas supply unit is introduced into the processing space.

Preferably, the facing electrode and the facing ground potential portion are electrically isolated from each other by using an annular insulating body. Further, a high frequency power and an additional high frequency power having different frequencies may be overlappingly applied to the high frequency electrode.

Preferably, the dielectric plate is extended to cover a surface of a side wall of the processing chamber. This configuration makes it possible to increase the impedance of the surfaces of the side walls of the processing chamber, thereby further improving the effect of an electrode impedance control function.

In accordance with the present plasma processing apparatus, the configuration and operation mentioned above makes it possible to improve the effect of an electrode impedance control function and also to effectively control a plasma density distribution.

### BRIEF DESCRIPTION OF THE DRAWINGS

The objects and features of the present invention will become apparent from the following description of embodiments given in conjunction with the accompanying drawings, in which:

FIG. 1 is a vertical sectional view showing a plasma etching apparatus in accordance with an embodiment of the present invention;

FIG. 2 is a view schematically illustrating an electrode impedance control operation in accordance with the embodiment of the present invention;

FIG. 3 is another view schematically illustrating the electrode impedance control operation in accordance with the embodiment of the present invention;

FIG. 4 is a view presenting experimental data (of an electron density distribution) regarding one example of the electrode impedance control operation in accordance with the embodiment of the present invention;

FIG. 5 is a view presenting experimental data (of an electron density distribution) regarding one example of the electrode impedance control operation in accordance with a comparative example;

FIG. 6 is a vertical sectional view showing a plasma etching apparatus in accordance with a modified example of the present embodiment; and

FIG. 7 is a vertical sectional view showing a plasma etching apparatus in accordance with another embodiment of the present invention.

### DETAILED DESCRIPTION OF THE EMBODIMENTS

Hereinafter, embodiments of the present invention will be described with reference to the accompanying drawings which forms a part hereof. However, the present invention is not limited thereto.

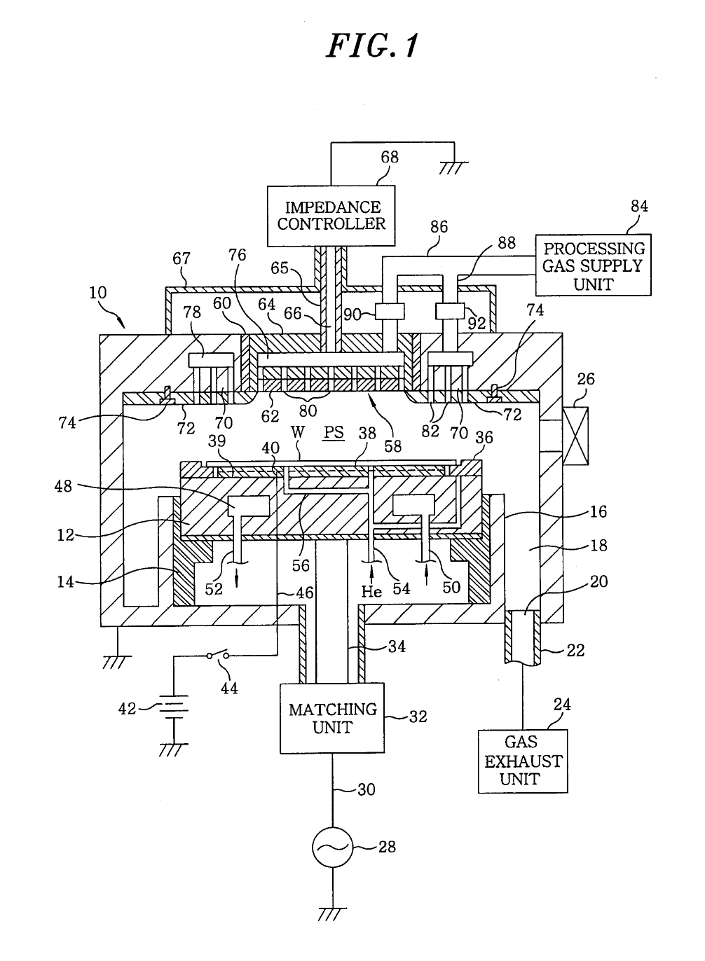

FIG. 1 shows a configuration of a plasma processing apparatus in accordance with a first embodiment of the present invention. The plasma processing apparatus is configured as a cathode-coupled and capacitively coupled plasma etching apparatus and has a cylindrical chamber (processing chamber) 10 made of metal such as aluminum or a stainless steel. The chamber 10 is frame grounded.

A disk-shaped susceptor 12 for supporting a target substrate to be processed, e.g., a semiconductor wafer W, is horizontally arranged within the chamber 10 as a lower electrode and also a high frequency electrode. The susceptor 12 is made of, e.g., aluminum, and is supported by means of a cylindrical insulating support 14 in a non-grounding state, i.e., in an electrically floating state. That is, the suscepter 12 is not grounded and electrically isolated from the grounded chamber 10. The cylindrical insulating support 14 extends vertically upwardly from the bottom of the chamber 10 and is made of, e.g., ceramic.

A conductive cylindrical support 16 extends vertically upwardly from the bottom of the chamber 10 along an outer circumference of the cylindrical insulating support 14. An annular exhaust passageway 18 is formed between the conductive cylindrical support 16 and an inner wall of the chamber 10. An exhaust port 20 is provided in the bottom of the exhaust passageway 18. A gas exhaust unit 24 is connected to the exhaust port 20 via an exhaust line 22. The gas exhaust unit 24 is provided with a vacuum pump, such as a turbo molecular pump, and is able to depressurize the processing space of the chamber 10 to a desired vacuum level. A loading/unloading through which the semiconductor wafer W is loaded or unloaded is formed in the sidewall of the chamber 10. A gate valve 26 for opening and closing the loading/unloading port is attached to the outer surface of the chamber 10.

A high frequency power supply 28 is electrically connected to the susceptor 12 via an RF cable 30, a matching unit 32 and a power supply rod 34. In this configuration, the high frequency power supply 28 outputs a first high frequency power of a predetermined frequency, e.g., 13.56 MHz, contributes to generate a plasma and inject ions into the semiconductor wafer W mounted on the susceptor 12. The RF cable 30 is made of, e.g., a coaxial cable. Received within the matching unit 32 is a matching circuit that serves to match the impedance of the high frequency power supply 28 with the impedance of loads (mainly the electrode and the plasma). The matching unit 32 further includes an RF sensor, a controller, a stepping motor and the like to be used in performing an auto-matching operation.

The susceptor 12 has a diameter greater than that of the semiconductor wafer W. The susceptor 12 has a major surface, i.e., a top surface, which is radially bisected into a central region, i.e., a wafer mounting portion, having substantially the same shape and size as that of the semiconductor wafer W and an annular peripheral portion extending outwardly from the wafer support portion. The semiconductor wafer W to be processed is mounted on the wafer mounting portion, while a focus ring 36 having an inner diameter slightly greater than the diameter of the semiconductor wafer W is attached to the annular peripheral portion. Depending on the etching target materials of the semiconductor wafer W, the focus ring 36 is made of one material of, e.g., Si, SiC, C and SiO₂.

An electrostatic chuck 38 for attracting the semiconductor wafer W is provided at the wafer support portion of the top surface of the susceptor 12. The electrostatic chuck 38 is fabricated by embedding a sheet-like or mesh-like conductor 40 into a film-shaped or plate-shaped dielectric body 39 and is integrally formed with or integrally fixed to the top surface of the susceptor 12. A DC power supply 42 provided outside the chamber 10 is electrically connected to the conductor 40 via a switch 44 and a covered wire 46. The electrostatic chuck 38 attracts and holds the semiconductor wafer W by using the Coulomb force generated by a DC voltage supplied from the DC power supply 42.

An annular coolant reservoir 48 extending, e.g., in a circumferential direction is formed within the susceptor 12. A coolant, e.g., cooling water, of a specific temperature is supplied from a chiller unit (not shown) to the coolant reservoir 48 via a line 50 and a line 52. The temperature of the semiconductor wafer W mounted on the electrostatic chuck 38 can be controlled according to the temperature of the coolant. In an effort to control the wafer temperature with increased accuracy, a thermally conductive gas, e.g., a helium gas, is supplied from a thermally conductive gas supply unit (not shown) to between the electrostatic chuck 38 and the semiconductor wafer W via a gas supply line 54 and a gas passage 56 formed within the susceptor 12.

An upper electrode or facing electrode 58 is attached at the ceiling of the chamber 10 in a non-grounding state, i.e., in an electrically floating state, to be faced with the susceptor 12 in a parallel and coaxial relationship. That is, the facing electrode 58 is not grounded and electrically isolated from the grounded chamber 10. More specifically, an opening is formed in the central portion of the ceiling of the chamber 10. The facing electrode 58 having a disk-like shape is engaged into the opening through an annular insulating body 60. The facing electrode 58 includes an electrode plate 62 directly facing the central portion of the susceptor 12 and an electrode support 64 supporting the electrode plate 62 on the rear (upper) side thereof. The electrode plate 62 is made of, e.g., Si, SiC or C and the electrode support 64 is made of, e.g., alumite treated aluminum.

The rear surface of the facing electrode 58 is connected (or grounded) to the ground potential via a conductive bar 66 and an impedance controller 68. The impedance controller 68 includes a variable impedance circuit having at least one variable reactance element. The impedance controller 68 varies the impedance of the variable reactance element by using an actuator, e.g., a stepping motor, thereby setting or controlling the impedance of the impedance circuit as a whole, i.e., the electrode impedance Z, to an arbitrary value. A cylindrical grounding conductor 67 is arranged around and radially outwardly of the conductive bar 66, with a cylindrical insulating body 65 therebetween.

At the ceiling portion of the chamber 10, an annular facing ground potential portion 70 integrally formed with the sidewall of the chamber 10 to face toward the susceptor 12 is disposed radially outside of the facing electrode 58, i.e., around the annular insulating body 60. The gap between the susceptor 12, and the facing electrode 58 and the facing ground potential portion 70 forms a plasma-generating space or processing space PS.

In the embodiment of the present invention, a dielectric plate, e.g., a quartz plate 72, are detachably attached to the surfaces (bottom surfaces) of the facing ground potential portions by bolts made of a resin material such as Vespel (the trademark of a polymer manufactured by DuPont's polyimide resin) or the like, so that the quartz plate 72 can make contact with and cover the surface (lower surface) of the facing ground potential portion 70. The function of the quartz plate 72 will be described later in detail.

In the facing electrode 58 and the facing ground potential portion 70, there is provided a shower head mechanism for introducing the processing gas into the processing space PS in the chamber 10. More specifically, the facing electrode 58 and the facing ground potential portion 70 are respectively provided with gas rooms 76 and 78 and gas injection openings 80 and 82 through which the processing gas injected from the gas cavities 76 and 78 into the processing space PS. In this regard, the gas injection openings 80 arranged in the central region penetrate the electrode support plate 64 and the electrode plate 62 of the facing electrode 58 from the top to the bottom in a vertical direction. Furthermore, the gas injection openings 82 arranged in the peripheral region penetrate the facing ground potential portion 70 and the quartz plate 72 in a vertical direction.

During plasma processing, a specific processing gas is supplied from a processing gas supply unit 84 to the gas rooms 76 and 78 through gas supply lines 86 and 88. The flow rate ratio of the processing gas supplied to the gas rooms 76 and 78 can be arbitrarily regulated by use of flow control valves 90 and 92 provided in the gas supply lines 86 and 88.

The individual operations of the respective parts arranged within the plasma etching apparatus, e.g., the gas exhaust unit 24, the high frequency power supply 28, the switch 44 of the DC power supply 42, the chiller unit (not shown), the impedance controller 68, the thermally conductive gas supply unit (not shown) and the processing gas supply unit 84, and the overall operation (sequence) thereof are controlled by an apparatus controller (not shown) including, e.g., a microcomputer.

In order to perform an etching operation in the plasma etching apparatus, the gate valve 26 is first opened and then the target semiconductor wafer W is loaded into the chamber 10 and mounted on the electrostatic chuck 38. Then, an etching gas (usually, a gaseous mixture) is introduced into the processing space PS in the chamber 10 from the processing gas supply unit 84 via the gas supply lines 86 and 88, the gas rooms 76 and 78 and the gas injection openings 80 and 82 in a specified flow rate and flow rate ratio. The pressure within the chamber 10 is set to a predetermined value by the gas exhaust unit 24.

Further, the high frequency power supply 28 is turned on to thereby output a specific high frequency power in a specific power. The high frequency power is supplied or applied to the susceptor (lower electrode) 12 via the RF cable 30, the matching unit 32 and the power supply rod 34. In addition, the switch 44 is turned on to generate an electrostatic adsorptive force by which the thermally conductive gas (helium gas) is confined in the contact interface between the electrostatic chuck 38 and the semiconductor wafer W. The etching gas injected from the gas injection openings 80 and 82 of the shower head mechanism is turned to a plasma as the high frequency power is electrically discharged in the processing space PS between the electrodes 12 (, and 58 and 70). The film formed on the major surface of the semiconductor wafer W is etched under the action of radicals or ions generated by the plasma.

Next, the operation of the plasma etching apparatus in accordance with the embodiment of the present invention is described. In the plasma etching apparatus described above, the upper electrode, i.e., the facing electrode 58, coaxially facing the susceptor 12 is electrically isolated from the chamber 10 of a ground potential. The impedance controller 68 is connected between the facing electrode 58 and the ground. The annular peripheral portions of the ceiling of the chamber 10 extending around the facing electrode 58, i.e., the surface of the facing ground potential portion 70, is covered by the quartz plate 72. It is preferred that the quartz plate 72 have a thickness of about 10 mm or more in order for the quartz plate 72 to produce the operational effects to be described below.

The impedance controller 68 can change upwards or control the plasma density distribution in a region just below the facing electrode 58 by variably controlling electrode impedance Z between the facing electrode 58 and the ground. Further, the quartz plate 72 provides an effect of increasing the impedance between the processing space PS and the facing ground potential portion 70. If the impedance between the processing space PS and the facing ground potential portion 70 is low, most of the electric current flows through the facing ground potential portion 70. This means that the flow of the electric current cannot be greatly changed by either increasing or decreasing the impedance (the electrode impedance Z) of the facing electrode 58. In contrast, if the impedance between the processing space PS and the facing ground potential portion 70 is set high, a considerable amount of electric current can flow through the facing electrode 58. For this reason, the flow of the electric current can be greatly heavily affected by the increase or decrease of the impedance (the electrode impedance Z) of the facing electrode 58.

This reduces the possibility that the plasma density distribution in the region just below the facing ground potential portion 70 is affected by the increase and decrease of the plasma density distribution in the region just below the facing electrode 58 when such increase and decrease of the plasma density distribution is performed by the impedance controller 68. There is no fear that abnormal discharge occurs because the bolts 74 for fixing the quartz plate 72 to the facing ground potential portion 70 are made of resin.

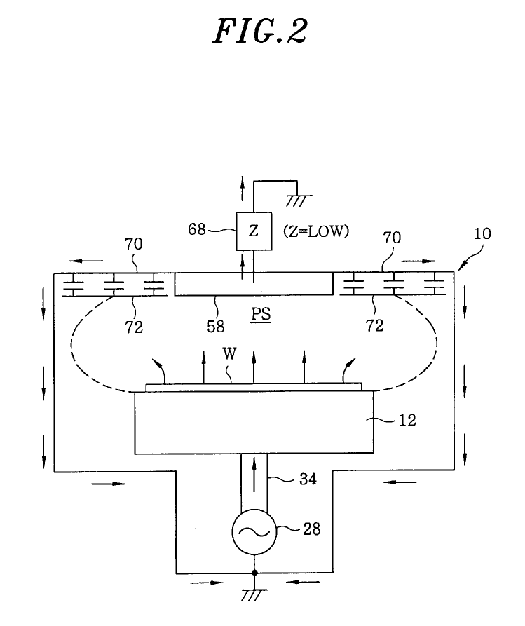

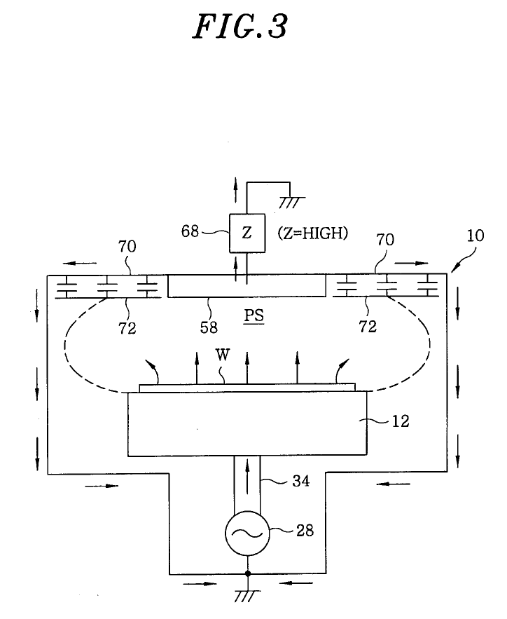

The operation in accordance with the embodiment of the present invention will now be described with reference to FIGS. 2 and 3. When the high frequency power supplied from the high frequency power supply 28 is applied to the susceptor 12, a plasma of the processing gas is generated in the processing space PS by the high frequency discharge between the susceptor 12 and the facing electrode 58, the high frequency discharge between the susceptor 12 and the facing ground potential portion 70 and the high frequency discharge between the susceptor 12 and the side wall of the chamber 10. The plasma thus generated is diffused in all directions, particularly in an upper direction and in a radially outward direction of the wafer W. A part of the electric current of the plasma flows from the facing electrode 58 toward the ground through the impedance controller 68 but the remaining electric current flows toward the ground through the facing ground potential portion 70 and the sidewall of the chamber 10. The electric current of the plasma flows toward the facing ground potential portion 70 through the quartz plate 72. In this connection, the quartz plate 72 may be regarded as a sheet-like fixed condenser.

When the electrode impedance Z in the impedance controller 68 is kept low as illustrated in FIG. 2, the electric current flowing to the facing electrode 58 is increased and, consequently, the plasma density in the region just below the facing electrode 58 is changed to be increased. Seeing that the plasma is diffused in all directions as set forth above, an electric current or plasma having a substantially high density exists in the region just below the facing ground potential portion 70, although the density is lower than that in the region just below the facing electrode 58.

Next, if the electrode impedance Z in the impedance controller 68 is kept high as illustrated in FIG. 3, the electric current flowing into the facing electrode 58 is decreased and, consequently, the plasma density in the region just below the facing electrode 58 is changed to be decreased. In this way, the flow of the electric current in the plasma, i.e., the plasma density can be changed by changing the electrode impedance Z.

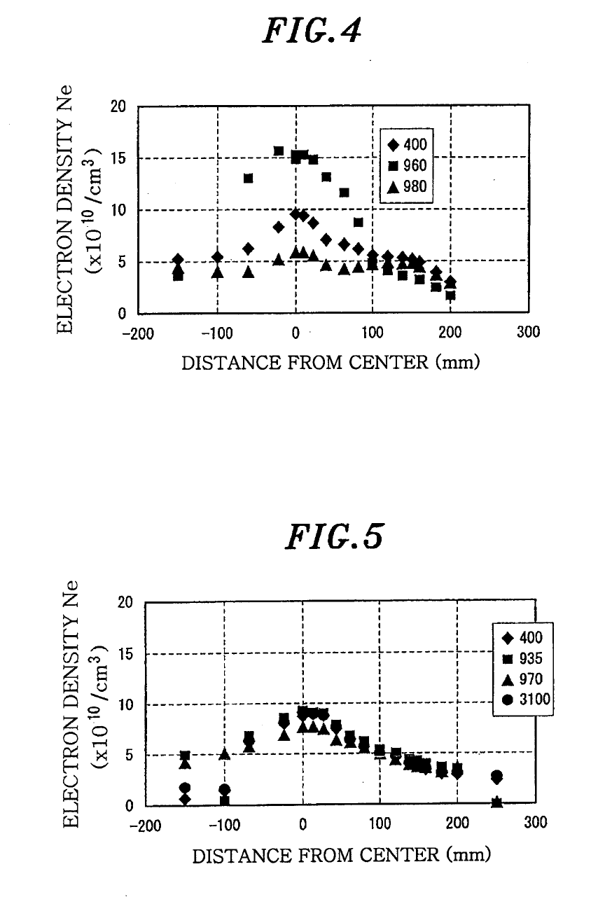

FIG. 4 presents experimental data regarding one example of the electrode impedance control operation in accordance with the embodiment of the present embodiment. In this experimental example, the variable reactance element of the impedance controller 68 is a variable condenser and the electron density is measured at thirty (30) or more impedance positions (equivalent to rotation angle values). Electron density distributions at three impedance positions “400”, “960” and “980” are presented in FIG. 4. The electron density distributions are greatly changed in the impedance positions “960” and “400”. The wafer has a diameter of 300 mm and the facing electrode 58 has a diameter of 160 mm.

As illustrated in FIG. 4, in case of the impedance position “960”, the electron density is remarkably high in the central region and its overall distribution resembles a steep mountain of a large height difference. More specifically, the electron density is about 5×010/cm³ at the wafer edge regions and about 15×10¹⁰/cm³ at the wafer center region, which is three times as great as the electron density at the edge regions. In contrast, the electron density in case of the impedance position “980” is sharply decreased at the center region and decreased a little at the edge regions. Therefore, the difference in electron density between the central region and the edge regions is small, thus making a generally flat electron density distribution as a whole. More specifically, the electron density is about 5×10¹⁰/cm³ in the highest central region and about 3×10¹⁰/cm³ in the lowest edge region. The electron density across the wafer region (−150 mm to 150 mm) is in a range of from about 3×10¹⁰/cm³ to 5×10¹⁰/cm³. In this manner, it is possible to greatly change the profile of the electron density distribution by controlling the electrode impedance in the impedance controller 68. It is also easy to ensure that the electron density distribution has a flat characteristic.

FIG. 5 presents experimental data regarding a test example of the electrode impedance control operation in accordance with a comparative example in which the quartz plate 72 is omitted. The electron density is measured in thirty (30) or more impedance positions as is the case in FIG. 4. Electron density distributions at four impedance positions “400”, “935”, “970” and “3100” are presented in FIG. 5. As illustrated in FIG. 5, the electron density shows a mountain-like distribution as a whole in which the central region protrudes more than twice as high as the edge portion. The profile (especially at the central region) does not change a lot depending on the impedance portions. As is apparent from the above, the impedance on the surface of the facing ground potential portion 70 is low in case of omitting the quartz plate 72. For this reason, the effect of controlling the electrode impedance with the impedance controller 68 is insufficient and it is quite difficult to arbitrarily change the profile of the electron density distribution. Further, the electron density distribution cannot have a substantially flat characteristic.

While the embodiment of the present invention has been described hereinabove, the present invention is not limited thereto. It may be arbitrarily changed or modified in many different ways.

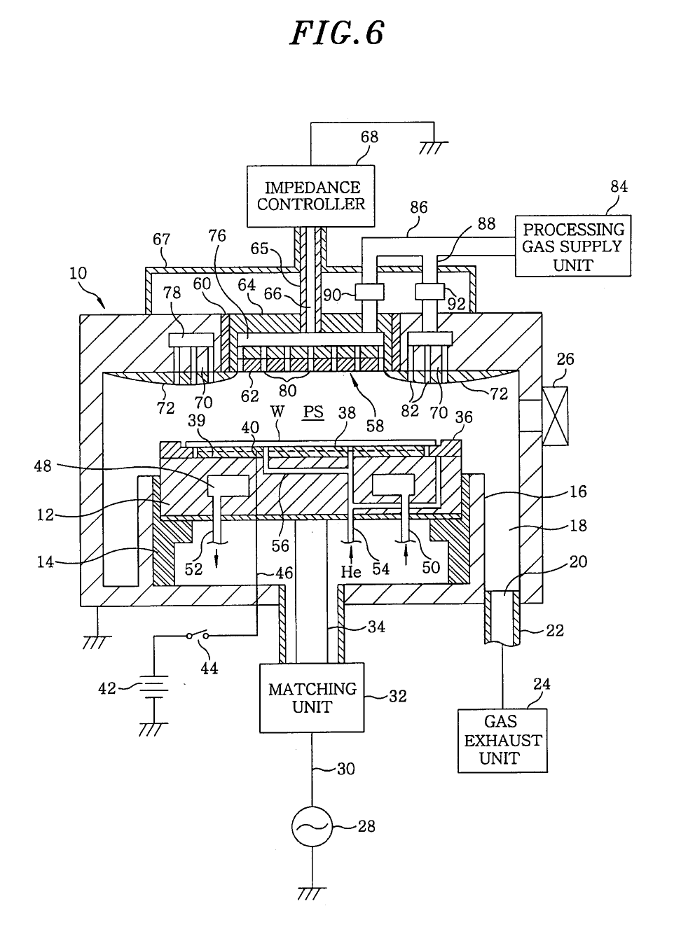

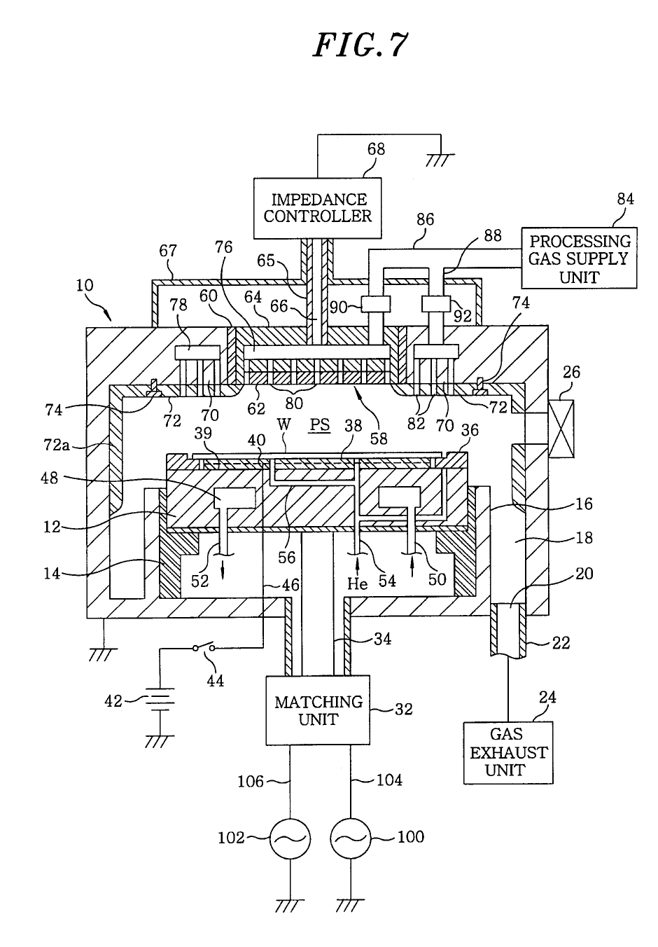

For example, it may be possible to employ a configuration in which the thickness of the quartz plate 72 changed in a radial direction. FIG. 6 shows a modified example in which the thickness of the quartz plate 72 is greatest near, or at the side closest to, the facing electrode 58 and is gradually reduced in a radially outward direction. This configuration ensures that the impedance in the facing ground potential portion 70 becomes greatest near the facing electrode 58. In addition, this configuration makes it possible to highlight the region in which the electron density distribution is influenced by the electrode impedance control of the impedance controller 68, i.e., the boundary between the region just below the facing electrode 58 and the remaining (surrounding) region thereof. It may also be possible to make the diameter of the facing electrode 58 substantially equal to or greater than the diameter of the semiconductor wafer W.

FIG. 7 shows a plasma etching apparatus in accordance with another embodiment of the present invention. The plasma etching apparatus of this embodiment includes two modifications. One of the modifications is in that the quartz plate 72 extends from the facing ground potential portion 70 on the ceiling surface of the chamber 10 to the side wall of the chamber 10. With this configuration, it becomes possible to increase the impedance of the side wall surface of the chamber 10 by side wall extension portion 72a of the quartz plate 72. This helps further increase controllability of the electron density distribution or the plasma density distribution by the impedance controller 68. It may also be possible to replace the quartz plate 72 with a dielectric plate made of other materials, e.g., an alumina-ceramic plate.

The other modification is in that two high frequency powers with different frequencies are applied to the susceptor 12 by a lower electrode dual frequency application method. More specifically, the plasma etching apparatus includes a first high frequency power supply 100 that outputs a first high frequency power having a specific frequency, e.g., 60 MHz, suitable for controlling the plasma density and a second high frequency power supply 102 that outputs a second high frequency power having a specified frequency, e.g., 13.56 MHz, suitable for controlling the self-biased voltage generated in the susceptor 12 and the ion energy led into the semiconductor wafer W. The first high frequency power output from the first high frequency power supply 100 is applied to the susceptor 12 via the RF cable 104, the matching unit 32 and the lower power supply rod 34. The second high frequency power output from the second high frequency power supply 102 is applied to the susceptor 12 via an RF cable 106, the matching unit 32 and the lower power supply rod 34. A matching circuit for the first high frequency power and a matching circuit for the second high frequency power are built in the matching unit 32. The impedance controller 68 includes a first variable impedance circuit for the first high frequency power and a second variable impedance circuit for the second high frequency power. The impedance controller 68 is configured to variably control the electrode impedance Z1 of the first variable impedance circuit and the electrode impedance Z2 of the second variable impedance circuit independently of each other.

The present invention is not limited to the plasma etching apparatus in accordance with the embodiments of the present invention but may be applied to other plasma processing apparatuses for performing plasma CVD, plasma oxidation, plasma nitridation, sputtering or the like.

Furthermore, the target substrate in accordance with the embodiment of the present invention is not limited to the semiconductor wafer. It may be possible to use various kinds of substrates for use in a flat panel display, a photo mask, a CD substrate, a printed board and the like.

While the invention has been shown and described with respect to the embodiments, it will be understood by those skilled in the art that various changes and modification may be made without departing from the scope of the invention as defined in the following claims.

What is claimed is:

1. A plasma processing apparatus comprising:
a vacuum-evacuable processing chamber;
a high frequency electrode provided in the processing chamber in an electrically floating state;
a high frequency power supply for applying a high frequency power to the high frequency electrode;
a facing electrode attached to the processing chamber in an electrically floating state to face the high frequency electrode;
a facing ground potential portion provided around the facing electrode in a grounded state;
an impedance controller for variably controlling an impedance of a high frequency power transmitting pass extending from a surface of the facing electrode to a ground potential;
a processing gas supply unit for supplying a processing gas into a processing space between the high frequency electrode, and the facing electrode and the facing ground potential portion; and
a dielectric plate arranged within the processing chamber to cover a surface of the facing ground potential portion.

2. The plasma processing apparatus of claim 1, wherein the dielectric plate is directly attached to the surface of the facing ground potential portion.

3. The plasma processing apparatus of claim 2, wherein the dielectric plate is attached to the surface of the facing ground potential portion by a bolt made of resin.

4. The plasma processing apparatus of claim 1, wherein the dielectric plate has a thickness varying in a radial direction of the facing electrode.

5. The plasma processing apparatus of claim 1, wherein the dielectric plate is a quartz plate.

6. The plasma processing apparatus of claim 1, wherein the high frequency electrode serves to mount a target substrate thereon.

7. The plasma processing apparatus of claim 1, wherein the facing electrode and the facing ground potential portion are provided with gas injection openings through which the processing gas fed from the processing gas supply unit is introduced into the processing space.

8. The plasma processing apparatus of claim 1, further comprising an annular insulating body which electrically isolates the facing electrode and the facing ground potential portion from each other.

9. The plasma processing apparatus of claim 6, further comprising an additional high frequency power supply for applying an additional high frequency power having a frequency different from a frequency of the high frequency power to the high frequency electrode.

10. The plasma processing apparatus of claim 1, wherein the dielectric plate is extended to cover a surface of a sidewall of the processing chamber.
